(19) United States
(12) Patent Application Publication
(10) Pub. No.: US 2009/0238995 A1
(43) Pub. Date: Sep. 24, 2009

(54) SHEET-LIKE PLASMA GENERATOR AND FILM DEPOSITION METHOD AND EQUIPMENT EMPLOYING SUCH SHEET-LIKE PLASMA GENERATOR

(75) Inventors: Tomoyasu Saitou, Kanagawa (JP); Takayuki Moriwaki, Kanagawa (JP)

Correspondence Address: BUCHANAN, INGERSOLL & ROONEY PC, POST OFFICE BOX 1404, ALEXANDRIA, VA, 22313-1404, US

(73) Assignee: Canon ANELVA Corporation, Kawasaki-shi (JP)

(21) Appl. No.: 12/091,505

(22) PCT Filed: Oct. 10, 2006
(86) PCT No.: PCT/JP2006/320180

§ 371 Date: Apr. 25, 2008

(30) Foreign Application Priority Data
Oct. 25, 2005 (JP) 2005-309810

(51) Int. Cl. C23C 16/513; H05H 1/24

(52) U.S. Cl. 427/569; 118/723 R; 422/186.04

(57) ABSTRACT

The present invention provides a sheet-like plasma generator in which film deposition area can be enlarged while making the film thickness distribution more uniform, and film deposition equipment employing such sheet-like plasma generator. The sheet-like plasma generator generates sheet-like plasma by passing a plasma beam, which let out from a plasma gun by means of a convergence coil, through a magnetic field formed by a sheet magnet assembly consisting of a pair of sheet magnets in the form of permanent magnets extending in the direction perpendicular to the advancing direction of the plasma beam and arranged in parallel to oppose each other, and deforming the plasma beam into a sheet-like plasma beam. The sheet magnet assembly includes at least one sheet magnet in which the repulsion field strength at a portion corresponding to the central side of the plasma beams is higher than that at a portion corresponding to the outer edge side of the plasma beam.

### TECHNICAL FIELD

The present invention relates to a sheet-like plasma generator and film deposition method and equipment employing such sheet-like plasma generator. Particularly, the present invention relates to the film deposition apparatus and method that are suited for use in deposing films on the large area substrates in the field of the manufacture of plasma display panels, for example.

### BACKGROUND

In those recent years, there have been demands for the mass-production of large-size substrates for displays, such as the liquid crystal display devices (which may be referred to hereinafter as “LCD” devices) and the plasma display devices (which may be referred to hereinafter as “PDP” devices).

In depositing thin films, such as the transparent electrically conductive films ITO, the front panel electrode protective layers of MgO and the like, on the large area substrates for displays such as LCD or PDP, attention has been focused on the ion plating method as the film deposition method that replaces the EB vapor deposition method or sputtering method, as demands for the manufacture of such panels or demands for higher definition panels are increasing. The ion plating method has a number of merits in that it permits the high rate film deposition and the high density and high quality film deposition, allowing for the large process margin. In addition, this method permits the films to be deposited on the large area substrate by controlling the magnetic field of the plasma beams. Among others, the hollow cathode-type ion plating method can be expected to be used for the film deposition on the large area substrates for the display types mentioned above.

In the hollow cathode-type ion plating method, the UR-type plasma gun that is developed by S. Urahonjo may be used as the plasma supply source, which is described in Japanese patent No. 1755055. This UR-type plasma gun consists of a hollow cathode and a plurality of electrodes, in which high density plasma may be generated by introducing Ar gas, and may be led into the thin film deposition chamber after the shape and trajectory of the plasma beam have been varied by passing it through the four different magnetic fields. In other words, the plasma beam that has been generated by the plasma gun may be passed through the magnetic fields developed by a sheet magnet assembly, in which the sheet magnet assembly consists of a pair of sheet magnets in the form of permanent magnets extending in the direction perpendicular to the advancing direction of the plasma beam and arranged in parallel with each other and opposite each other. This may cause the plasma beam to be deformed into a sheet-like plasma beam being expanded flatly and widely.

There is also a technology that has been developed for irradiating, over the wide area, the vapor disposition material placed on its dish with this sheet-like plasma beam expanded widely and flatly (as disclosed in Japanese patent application H9 (1997)-78230 now opened for the public examination). According to this publication, it is described that the vapor disposition material, such as MgO, on its dish may be irradiated over the wide area with such sheet-like plasma beam, thus allowing for the use of the different types of the vapor disposition material supply sources so that thin films can be formed from such vapor disposition materials on the wide area of substrates.

One example of the film deposition method using the conventional film deposition apparatus 100 described above is illustrated in FIGS. 11 and 12. FIG. 11 is a schematic side view illustrating one example of the conventional film deposition method, and FIG. 12 is a schematic plan view of the apparatus in FIG. 11. FIG. 12 shows the state as viewed in the direction of X in FIG. 11, and FIG. 11 shows the state as viewed in the direction of Y in FIG. 12.

Within the film deposition chamber of the film deposition apparatus 100 from which the air can be evacuated to place the film deposition chamber in the vacuum state, a dish 32 on which any suitable vapor deposition material 31 such as MgO may be placed is disposed on the lower portion. A substrate 33 (for example, a large size substrate for the display) on which a film is to be deposited is disposed on the upper portion within the film deposition chamber 30 so that it can face opposite the dish 32. When a film such as the transparent electrically conductive film ITO or MgO film is deposited on each of the substrates 33 successively, those substrates may be carried on a substrate holder (not shown) successively at regular intervals as indicated by an arrow 43.

In the embodiment of the apparatus shown in FIGS. 11 and 12, a plasma gun 20 is provided outside the film deposition chamber 30, and consists of an electrode magnet 22 and an electrode coil 23, in which the electrode magnet 22 and electrode coil 23 are arranged co-axially along the substantially horizontal axis as shown in FIG. 11. As an alternative embodiment, the plasma gun 20 may be provided within the film deposition chamber 30, although this is not shown.

A convergence or focusing coil 26 is provided on the downstream side of the electrode coil 23 (that is, in the advancing direction of the plasma beam) so that it can lead the plasma beam 25 from the plasma gun 20 into the film deposition chamber 30.

Furthermore, on the downstream side of the convergence coil 26, a sheet magnet assembly is provided which consists of a pair of sheet magnets in the form of permanent magnets extending in the direction perpendicular to the advancing direction of the plasma beam 25 and arranged in parallel with and opposite each other. As described above, the plasma beam 25 going forward into the film deposition chamber 30 may be passed through the magnetic field developed by the pair of permanent magnets. While the plasma beam 25 is being passed through the magnetic field, it may be flattened into a sheet-like plasma beam 28. The sheet magnet assembly may include one or more pairs of sheet magnets. In the example of the conventional apparatus as shown in FIGS. 11 and 12, the sheet magnet assembly including two pairs of sheet magnets 29, 29 is provided.

Although the sheet magnets 29, 29 are provided within the film deposition chamber 30 in the example shown FIGS., 11 and 12, they may also be provided outside the film deposition chamber 30.

Any suitable vapor deposition material 31 is placed on its dish 32 so that a film may be deposited on the substrate 33. The substrate 33 on which the film is being deposited may be placed on its holder (not shown). Then, the air in the vacuum chamber 30 may be evacuated as indicated by an arrow 42 so that the vacuum chamber 30 can be placed in the particular degree of vacuum, while any suitable reaction gas may be supplied into the vacuum chamber as indicated by an arrow 41.

When the vacuum chamber 30 is placed in the above state, any suitable plasma gas such as argon (Ar) may be introduced into the plasma gun 20 as indicated by arrow 40. The plasma gun 20 may produce a plasma beam 25, which may then be focused by the magnetic field developed by the convergence or focusing coil 26 so that it can be expanded over a particular wide range. As the plasma beam 25 is being expanded like a column having a particular diameter as shown in FIG. 4 (a) and FIG. 5 (a), it may be led into the vacuum chamber 30. Then, the plasma beam 25 may then be passed through the respective magnetic fields developed by each pair of sheet magnets 29, 29. When passing through the respective magnetic fields developed by each pair of sheet magnets 29, 29, the plasma beam 25 may be deformed into a flat sheet-like plasma beam 28.

The sheet-like plasma beam 28 may go to an anode magnet 34 below the vapor deposition material dish 32 where it may be deflected by the magnetic field developed by the anode magnet 34 so that it can be attracted toward the dish 31. The sheet-like plasma beam 28 may then heat the vapor deposition material 31 on its dish. The part of the vapor deposition material 31 that has been heated by the plasma beam 28 may be evaporated. As it is evaporated, the material 31 may then reach the substrate 33 on its holder (not shown) moving in the direction of an arrow 43 where the film may be formed on the substrate 33.

### SUMMARY

In the conventional film deposition apparatus 100 described above and shown in FIGS. 11 and 12, the conventional sheet-like plasma generator is employed, in which the plasma beam may be generated by the plasma gun, which may then be passed through the magnetic fields developed by the pairs of sheet magnets so that it can be deformed into the sheet-like plasma beam being expanded into a flat shape.

In the conventional method that may be practiced by the conventional film deposition apparatus including the sheet-like plasma generator, the film deposition area may be increased, but the uniformity of the film thickness remains yet to be improved.

Specifically, it is found from the experiments that have been conducted by the inventors of the current patent application that the conventional method described above exhibits the ion flux distribution as shown in FIG. 10, which indicates the degree of the plasma beam distribution over the surface of the vapor deposition materials. It is noted in FIG. 10 that the Y-axis shows the ion strength (arbitrary average), and the X-axis shows the distance (mm) over which the plasma beam will be deformed (or expanded) into a sheet shape in the direction of an arrow x in FIG. 12, with the center of the sheet-like plasma beam 28 being designated as the origin (0).

It is also noted that the film being deposited on the surface of the substrate has the similar profile corresponding to the form in FIG. 10, in which the film has the greatest thickness at the center (one peak), which is then decreasing gradually toward the outer edges (both sides). This shows that the uniformity of the film thickness distribution is insufficient when the film is deposited on the wide area of the substrate.

The possible cause for this is that when the plasma beam is generated by the plasma gun, and is then going toward the film deposition chamber as it is being expanded over the particular range, for example, it is being formed like the column having the particular diameter, the plasma will be concentrated on the center of the plasma beam as compared with the outer edges of the plasma beam. Accordingly, it may be thought that the rate at which the vapor deposition material is evaporated will become higher when it is irradiated with the center portion of the plasma beam, than when it is irradiated with the outer edges of the plasma beam on both the sides of the center portion. As a result, the film thickness distribution may be such that the thickness becomes thicker toward the center while it becomes less thick on the outer edges (both sides). This means that the uniform film thickness distribution cannot be achieved when the film is deposited on the wide area of the substrate.

In light of the problems of the prior art described above, one object of the present invention is to provide a sheet-like plasma generator that is capable of expanding the area of the substrate on which the film is to be deposited and providing the more uniform film deposition distribution over the expanded area of the substrate. A film deposition method and apparatus employing the sheet-like plasma generator are also provided.

In order to achieve the above object, the sheet-like plasma generator includes a sheet magnet assembly consisting of a pair of sheet magnets comprising permanent magnets extending in a direction perpendicular to the advancing direction of the plasma beam and arranged in parallel with each other and opposite each other, wherein the plasma beam passes through the magnetic field developed by the sheet magnets so that it can be deformed into a sheet-like plasma beam.

In the specific form of the sheet-like plasma generator, the sheet magnet assembly includes at least one of the sheet magnets provides a repulsion magnet field strength at a portion corresponding to the central part of the plasma beam that is higher than that at a portion corresponding to the outer edge sides of the plasma beam.

In the above description, the at least one sheet magnet that may provide a repulsion magnet field strength at the portion corresponding to the central side of the plasma beam that is higher than that at the portion corresponding to the outer edge side of the plasma beam may be divided into several segments in the direction perpendicular to the plasma beam.

For the at least one sheet magnet that is divided into several segments, in this case, the permanent magnets at the portion corresponding to the central part of the plasma beam may be located closer to the plasma beam than the permanent magnets at the portion corresponding to the outer edge side of the plasma beam, and the distance between the permanent magnets facing opposite each other at the portion corresponding to the central part may be smaller than the distance between the permanent magnets facing opposite each other at the outer edge side.

For the alternative form of the at least one sheet magnet that is divided into several segments, the residual magnetic flux provided by the permanent magnets at the portion corresponding to the central part of the plasma beam may be greater than the residual magnetic flux provided by the permanent magnets at the portion corresponding to the outer edge side of the plasma beam, and the repulsion magnetic strength provided by the permanent magnets facing opposite each other at the portion corresponding to the central part may be higher than the repulsion magnetic strength provided by the permanent magnets facing opposite each other at the portion corresponding to the outer edge side.

In order to achieve the object mentioned earlier, a film deposition apparatus may be used in conjunction with any of the embodiments of the sheet-like plasma generator of the present invention described above, wherein the film deposition apparatus includes a film deposition chamber from which the air may be evacuated to place the film deposition chamber in the vacuum state, and a vapor deposition material dish arranged within the film deposition chamber and on which any suitable vapor deposition material may be placed, and wherein a substrate on which a film is being deposited is held in the position facing opposite the vapor deposition material dish and spaced away from the same, and the film deposition may be performed on the substrate by exposing the vapor deposition material to the sheet-like plasma beam generated by the sheet-like plasma generator, thereby causing the vapor deposition material to evaporate.

In the above case, the substrate on which a film is being deposited may be capable of moving in parallel with the film deposition material dish. Then, the film deposition may be performed on substrates successively while they are moving.

In order to achieve the object mentioned earlier, a film deposition method may be used in conjunction with any of the embodiments of the sheet-like plasma generator of the present invention described above, wherein the film deposition method includes steps of holding a substrate on which a film is being deposited in the position facing opposite the vapor deposition material dish placed within a film deposition chamber from which the air can be evacuated to place it in the vacuum state and spaced away from the vapor deposition material on its dish, and depositing a film on the substrate by exposing the vapor deposition material to the sheet-like plasma beam generated by the sheet-like plasma generator, thereby causing the vapor deposition material to evaporate

In the above case, the substrate on which a film is being deposited may be capable of moving in parallel with the film deposition material dish. Then, the film deposition may be performed on substrates successively while they are moving.

In the sheet-like plasma generator that may be used in conjunction with the film deposition apparatus and method described above, the plasma gun that produces a plasma beam may be disposed outside the film deposition chamber and the sheet magnet assembly may be disposed within the film deposition chamber, or both the plasma gun and sheet magnet assembly may be disposed outside the film deposition chamber.

In the sheet-like plasma generator, the sheet magnet assemblies include at least one sheet magnet assembly that may provide the repulsion magnetic field having the strength that is higher at the portion corresponding to the central part of the plasma beam than that at the portion corresponding to the outer edge side of the plasma beam, whereby the plasma beam generated by the plasma gun and drawn through the convergence coil passes through the magnetic field developed by the sheet magnet assembly in order to be deformed into the sheet-like plasma beam.

The resulting sheet-like plasma beam can then be traveling toward the vapor deposition material on its dish within the film deposition chamber, as it is being expanded over the particular wide range and like a column having the particular diameter, thus permitting the repulsion magnetic field strength at the portion corresponding to the central part of such plasma beam to be higher than that at the portion corresponding to the outer edge side of the plasma beam.

Then, the density of the plasma passing through the central side portion of the sheet magnet assembly can be distributed toward the outer edges on both sides of the central side portion. In this way, the plasma of the sheet-like plasma beam to which the vapor deposition material is exposed can be prevented from being concentrated on the central side rather than the outer edge side.

In other words, the ion flux distribution over the vapor deposition material surface may be varied from the shape of the steep mountain with only one peak as shown in FIG. 10 into a more flat shape. In this way, the profile of the film being deposited on the substrate can be so flattened as to permit the film deposition to occur over the wide area of the substrate and with the uniform film thickness distribution.

It may be appreciated from the above that the film deposition apparatus and method according the present invention allow the profile of the film being deposited on the substrate to be so flattened as to permit the film deposition to occur over the wide area of the substrate and with the uniform film thickness distribution.

### BRIEF DESCRIPTION OF DRAWINGS

FIG. 1 is a schematic side diagram illustrating one example of the sheet-like plasma generator and the film deposition apparatus employing such sheet-like plasma generator in accordance with one embodiment of the present invention;

FIG. 2 is a schematic plan diagram of FIG. 1;

FIG. 3 (a) is a plan view illustrating the sheet magnet assembly in the sheet-like plasma generator shown in FIGS. 1 and 2, in which one sheet magnet in the sheet magnet assembly is divided into three segments along the direction perpendicular to the plasma beam;

FIG. 3 (b) is a plan view illustrating another form of the sheet magnet assembly in the sheet-like plasma generator;

FIG. 3 (c) is a plan view illustrating another example of the sheet magnet portion in the embodiment shown in FIG. 3 (b);

FIG. 4 is provided to describe the sheet magnet assembly, in which (a) illustrates an example of the layout of the sheet magnet assembly in the conventional sheet-like plasma generator, and (b) through (e) correspond to FIG. 4 (a), illustrating an example of the layout of the sheet magnet assembly in the sheet-like plasma generator in accordance with an embodiment of the present invention;

FIG. 5 is provided to describe the sheet magnet assembly, in which (a) illustrates an example of the structure of the sheet magnet assembly in the conventional sheet-like plasma generator, and (b) and (c) correspond to FIG. 5 (a), illustrating an example of the structure of the sheet magnet assembly in the sheet-like plasma generator in accordance with an embodiment of the present invention;

FIG. 6 represents the respective ion flux distributions in graph forms that may be formed on the surface of the vapor deposition material by the sheet-like plasma that may be provided by the conventional sheet-like plasma generator in which the conventional sheet magnet assembly is employed and by the sheet-like plasma that may be provided by the sheet-like plasma generator of an embodiment of the present invention in which the sheet magnet assembly of the form shown in FIG. 4 (b) is employed;

FIG. 7 represents the respective ion flux distributions in graph forms that may be formed on the surface of the vapor deposition material by the sheet-like plasma that may be provided by the conventional sheet-like plasma generator in which the conventional sheet magnet assembly is employed and by the sheet-like plasma that may be provided by the sheet-like plasma generator of an embodiment of the present invention in which the sheet magnet assembly of the form shown in FIG. 5 (b) is employed;

FIG. 8 represents another example of the respective ion flux distributions in graph forms that may be formed on the surface of the vapor deposition material by the sheet-like plasma that may be provided by the conventional sheet-like plasma generator in which the conventional sheet magnet assembly is employed and by the sheet-like plasma that may be provided by the sheet-like plasma generator of an embodiment of the present invention in which the sheet magnet assembly of the form shown in FIG. 5 (b) is employed;

FIG. 9 represents the film thickness distribution in graph forms that may be obtained when the film is deposited using the sheet-like plasma generator and film deposition apparatus in accordance with an embodiment of the present invention, and the film thickness distribution in graph forms that may be obtained when the film is deposited using the conventional sheet-like plasma generator and film deposition apparatus;

FIG. 10 represents the ion flux distribution on the surface of the vapor deposition material in the conventional film deposition apparatus;

FIG. 11 is a schematic side view illustrating one example of the conventional sheet-like plasma generator and the conventional film deposition apparatus using such sheet-like plasma generator; and

FIG. 12 is a schematic plan view of FIG. 11.

### BEST MODE OF EMBODYING THE INVENTION

Now, some embodiments of the present invention will be described in further detail by referring to the accompanying drawings.

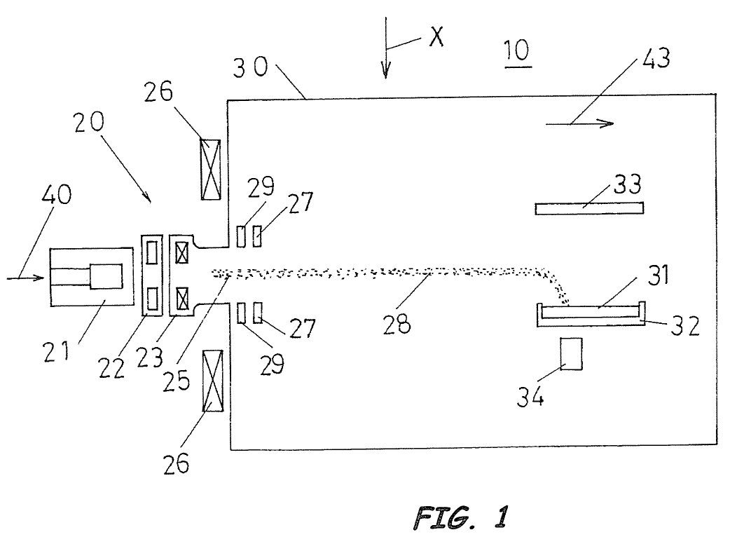

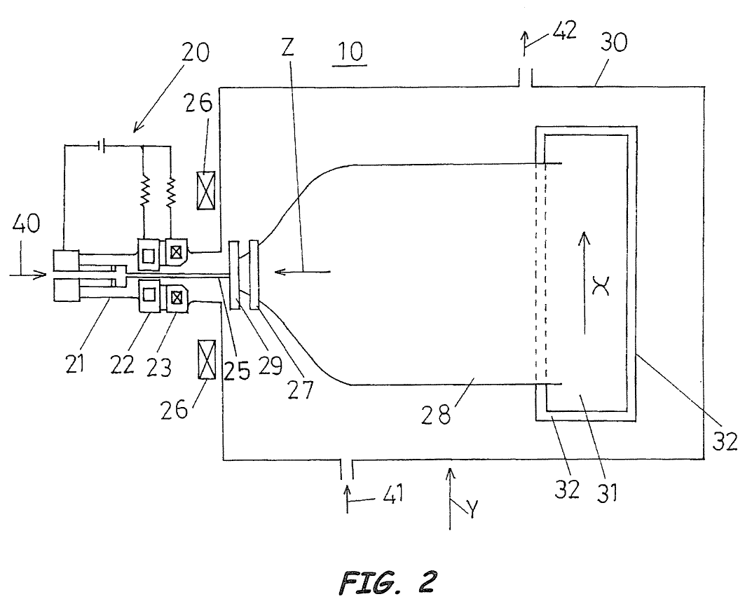

FIG. 1 is a side view illustrating the general structure of one example of the film deposition apparatus 10 including the sheet-like plasma generator in accordance with the present invention. FIG. 2 is a plan view illustrating the general structure of the film deposition apparatus 10 shown in FIG. 1. FIG. 2 shows the state of the apparatus 10 as viewed in the direction of an arrow X in FIG. 1, and FIG. 1 shows the state of the apparatus 10 as viewed in the direction of an arrow Y in FIG. 2.

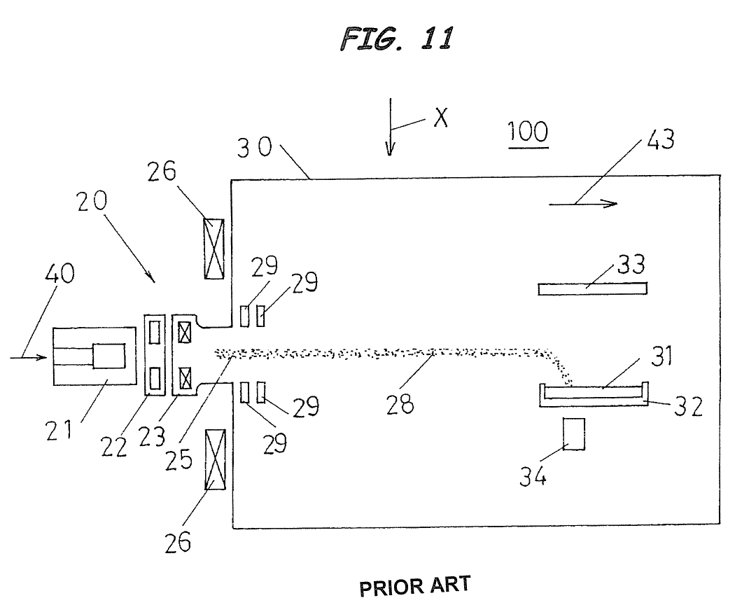

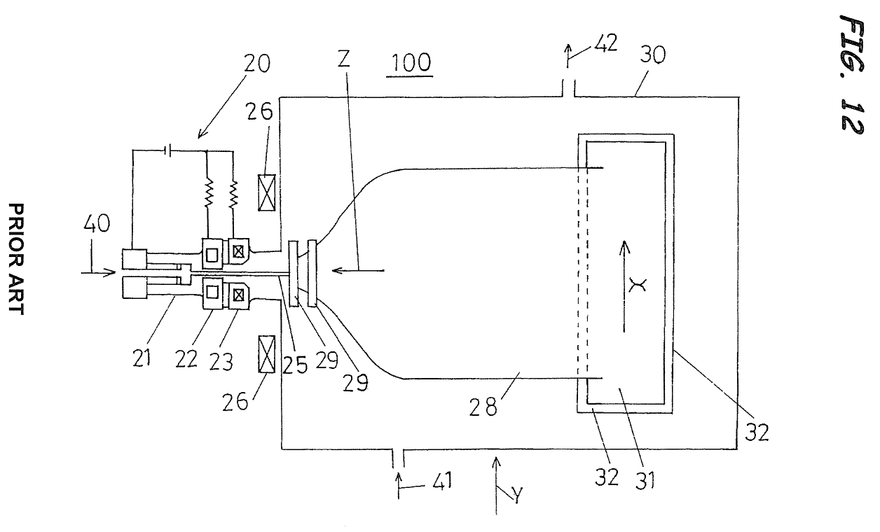

The structure of the film deposition apparatus 10 including the sheet-like plasma generator is similar to that of the conventional film deposition apparatus 100 including the sheet-like plasma generator that has been described above in the section “Background” in connection with FIGS. 11 and 12. The components of the film deposition apparatus 10 including the sheet-like plasma generator that are common to those of the film deposition apparatus 100 including the sheet-like plasma generator are given the same reference numerals, and are not described to avoid the duplicate description.

A plasma gun 20 may generate a plasma beam 25 which may be provided through a convergence or focusing coil 26. This plasma beam 25 may travel toward a film deposition chamber, in which it may be passed through the magnetic fields developed by a pair of sheet magnets 29, 27 in the form of permanent magnets extending in the direction perpendicular to the traveling direction of the plasma beam 25 and arranged in parallel and opposite each other. By passing through the magnetic fields, the plasma beam 25 may be formed into a flat sheet-like plasma beam 28 as shown in FIGS. 1 and 2.

The sheet-like plasma generator in accordance with the present invention may also provide the plasma beam 25 that may travel as it is being expanded over a particular range, for example, it is being formed like a column having a particular diameter, similarly to the conventional sheet-like plasma generator that has been described above in the section “Background” in connection with FIGS. 11 and 12. Then, this plasma beam 25 may be deformed by the sheet magnets into the flat sheet-like plasma beam 28.

In the sheet-like plasma generator in accordance with the present invention, the sheet magnet assembly include at least one sheet magnet 27 that may provide the repulsion magnetic field having the strength that is higher at the portion corresponding to the central side of the plasma beam than that at the portion corresponding to the outer edge side of the plasma beam 25.

In the embodiment shown in FIG. 1 through FIG. 3 (c), one of the sheet magnets, which is identified by 27, may provide the repulsion magnetic field having the strength that is higher at the portion corresponding to the central side of the plasma beam 25 than that at the portion corresponding to the outer edge side of the plasma beam 25. In contrast, one of the sheet magnets, which is identified by 29 in FIG. 1 through FIG. 3 (c), corresponds to the sheet magnet employed in the conventional sheet-like plasma generator that may provide the repulsion magnetic field in which there is no difference in the strength between the portion corresponding to the central side of the plasma beam 25 and the portion corresponding to the outer edge side of the plasma beam 25.

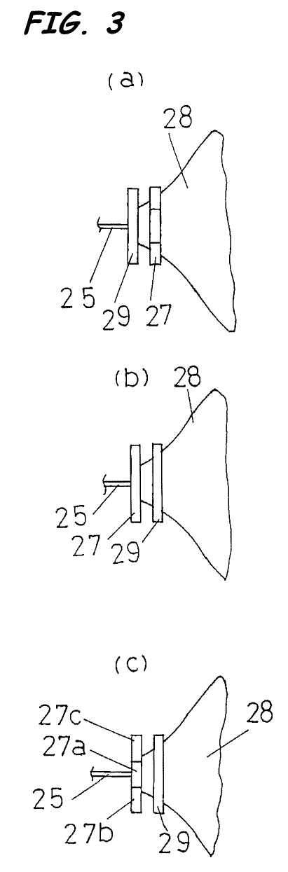

In the embodiment of FIG. 1 through FIG. 3 (c), the sheet magnet assembly includes two pairs of sheet magnets 27, 29 that are arranged in direction in which the plasma beam 25 travels toward the film deposition chamber 30, but the present invention is not limited to this embodiment. Rather, the sheet magnet assembly that includes more than two pairs of sheet magnets may be provided, but even in this case, it is required that at least one of the sheet magnets in each pair, as identified by 27, provide the repulsion magnetic field having the strength that is higher at the portion corresponding to the central side of the plasma beam 25 than that at the portion corresponding to the outer edge side of the plasma beam 25. In this case, the sheet magnet 27 may be located closer to the vapor deposition material 31 placed within the film deposition chamber 30 as shown in FIGS. 1 and 2, or may be located farther from the vapor deposition material 31 within the film deposition chamber 30 as shown in FIG. 3 (b). Either of the two options may be chosen as required.

Although this is not shown, a sheet magnet assembly may only include one pair of sheet magnets 27 that are arranged in the direction in which the plasma beam 25 travels toward the film deposition chamber 30 so that the sheet magnets 27 can provide the repulsion magnetic field having the strength that is higher at the portion corresponding to the central side of the plasma beam 25 than that at the portion corresponding to the outer edge side of the plasma beam 25.

In the embodiment shown in FIGS. 1 and 2, it is described that the pair of sheet magnets 29, 27 is provided within the film deposition chamber 30 as for the example of the prior art shown in FIGS. 11 and 12. Alternatively, the pair of sheet magnets 27, 29 may be provided outside the film deposition chamber 30.

In either case, as the pair of sheet magnets 29, 27 includes at least one sheet magnet 27 that can provide the repulsion magnetic field having the strength that is higher at the portion corresponding to the central side of the plasma beam 25 than that at the outer edge side of the plasma beam 25, the density of the plasma passing through the central side of the sheet magnet 27 can be distributed toward the outer edge side. In this way, the plasma can be prevented from being concentrated on the central side more than the outer edge side when the vapor deposition material 31 placed within the film deposition chamber 30 is irradiated with the sheet-like plasma beam 28. Accordingly, the film being deposited on the substrate 33 can have the flattened profile so that it can have the uniform film thickness distribution over the wide area.

In the sheet-like plasma generator, the sheet magnet 27 that provides the repulsion magnetic field having the strength that is higher at the portion corresponding to the central side of the plasma beam 25 than that at the portion corresponding to the outer edge side of the plasma beam 25 may have the form in which the sheet magnet 27 may be divided into several segments in the direction perpendicular to the direction in which the plasma beam 25 is traveling forward.

By doing this, it is easier to permit the sheet magnet 27 to provide the repulsion magnetic field having the strength that is higher at the portion corresponding to the central side of the plasma beam 25 than that at the portion corresponding to the outer edge side of the plasma beam 25 as described below.

FIG. 3 (a) shows an example of the sheet magnet 27 in the sheet-like plasma generator in the embodiment shown in FIGS. 1 and 2, in which the sheet magnet 27 is divided into three segments in the direction perpendicular to the direction in which the plasma beam 25 is traveling forward.

FIG. 3 (c) also shows an example of the sheet magnet 27 in the sheet-like plasma generator in the embodiment shown in FIG. 3 (b), in which the sheet magnet 27 is divided into three segments in the direction perpendicular to the direction in which the plasma beam 25 is traveling forward.

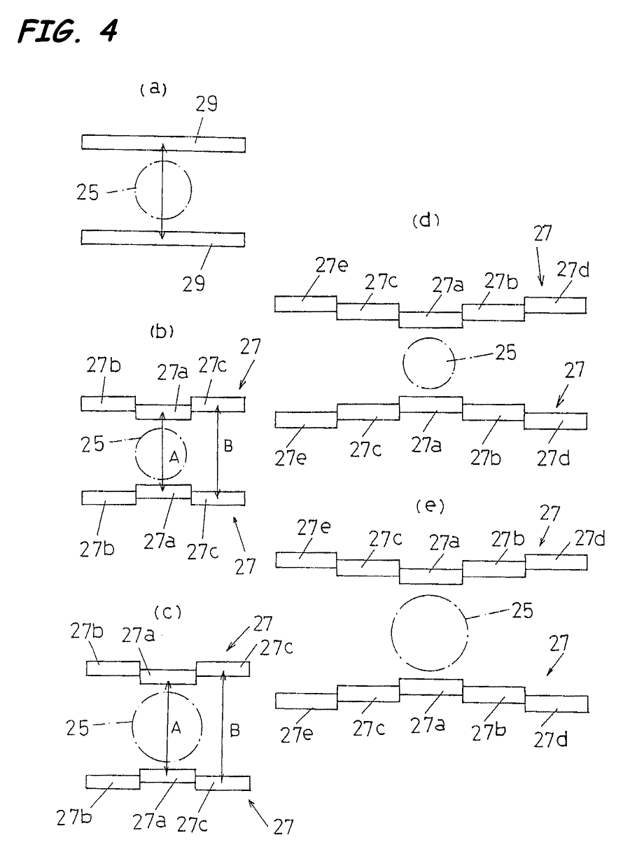

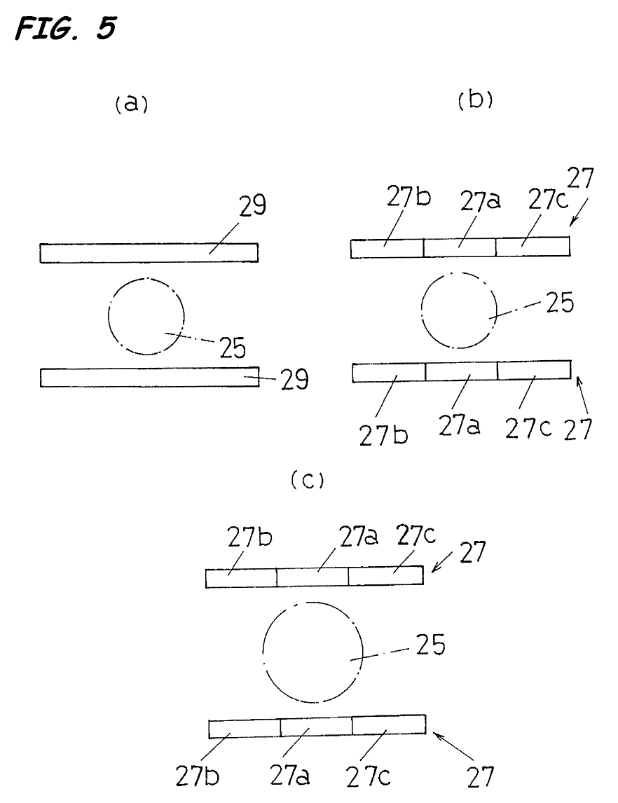

The examples of the preferred arrangement and structure of the sheet magnet 27 that is divided into several segments in the direction perpendicular to the direction in which the plasma beam 25 is traveling forward will be described below by referring to FIGS. 4 (a) through 4 (c) and FIGS. 5 (a) through 5 (c).

FIGS. 4 (a) through 4 (c) and FIGS. 5 (a) through 5 (c) illustrate examples of the respective arrangement and structure for the sheet magnet 29 in the conventional sheet-like plasma generator and for the sheet magnet 27 in the inventive sheet-like plasma generator, both as viewed in the direction of an arrow Z in FIG. 2.

In the case where the sheet magnet 27 that provides the repulsion magnetic field having the strength that is higher at the portion corresponding to the central side of the plasma beam 25 than that at the portion corresponding to the outer edge side of the plasma beam 25 is divided into several segments, the sheet magnet 27 may have the following form. For example, the sheet magnet 27 that is divided into several segments may be formed by two pairs of permanent magnets wherein the one pair of permanent magnets at the portion corresponding to the central side of the plasma magnet 25 may be located closer to the plasma beam 25 than the other pair of permanent magnets at the portion corresponding to the outer edge side of the plasma beam 25, and wherein the gap between the two permanent magnets facing opposite each other at the portion corresponding the central side may be smaller than the gap between the two permanent magnets facing opposite each other at the portion corresponding to the outer edge side.

When the sheet magnet 27 is divided into several segments in the direction perpendicular to the direction in which the plasma beam 25 is traveling forward, the repulsion magnetic field strength that is provided at the portion corresponding to the central side of the plasma beam 25 may be higher than the repulsion magnetic field strength that is provided at the portion corresponding to the outer edge side of the plasma beam 25. This can be accomplished easily as described below.

FIGS. 4 (b) and (c) show the example in which the sheet magnet 27 is divided into three segments, wherein the permanent magnets 27a, 27a at the portion corresponding to the central side of the plasma beam 25 are located closer to the plasma beam 25 than the permanent magnets 27b, 27b, 27c, 27c at the portion corresponding to the outer edge side of the plasma beam 25. In this way, the gap A between the permanent magnets 27a, 27a facing opposite each other at the portion corresponding to the central side can be smaller than the respective gaps B between the permanent magnets 27b, 27b facing opposite each other and between the permanent magnets 27c, 27c facing opposite each other at the portion corresponding to the outer edge side.

In contrast, FIG. 4 (a) shows the example of the sheet magnet 29 in the conventional sheet-like plasma generator, in which there is no difference in the strength between the respective repulsion magnetic fields provided at the portion corresponding to the central side of the plasma beam 25 and at the portion corresponding to the outer edge side of the plasma beam 25. It should be noted that the gap between the permanent magnets facing opposite each other at the portion corresponding to the central side of the plasma beam 25 and the gap between the permanent magnets facing opposite each other at the portion corresponding to the outer edge side of the plasma beam 25 are the same, and the repulsion magnetic field strength that is provided by the permanent magnets at the portion corresponding to the central side and the repulsion magnetic field strength that is provided by the permanent magnets at the portion corresponding to the outer edge side are the same.

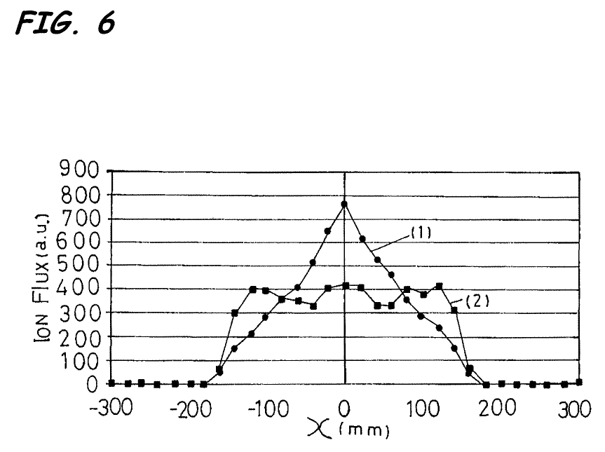

FIG. 6 is a diagram showing, in graph forms, the two different ion flux distributions formed on the surface of the vapor deposition material 31 by the sheet-like plasma beam 28 generated under the same conditions for both cases, in which one represents the ion flux distribution for the conventional sheet-like plasma generator including only the conventional sheet magnet 29 shown in FIG. 4 (a) and the other represents the ion flux distribution for the sheet-like plasma generator of the present invention including the modified form 27 of the sheet magnet 29 shown in FIG. 4 (b).

As demonstrated by the experiments conducted by the inventors of the current patent application, the ion flux distribution for the conventional sheet-like plasma generator including the conventional sheet magnet 29 shown in FIG. 4 (a) presents a steep mountain shape having one high peak as shown in FIG. 6 (1), whereas the ion flux distribution for the sheet-like plasma generator of the present invention presents a smooth mountain shape having several low peaks as shown in FIG. 6 (2).

From the above results, it is found that the plasma that evaporates the vapor deposition material 31 can be improved so that it can have the distribution having the smooth mountain shape. Thus, the film deposition apparatus 10 of the present invention that is included in the sheet-like plasma generator of the present invention allows the film thickness distribution of the film being deposited on the surface of the substrate 33 to be flattened and to be uniform over the wide area.

It should be understood that when the sheet magnet 27 that provides the repulsion magnet field having the strength that is higher at the portion corresponding to the central side of the plasma beam 25 than that at the portion corresponding to the outer edge side of the plasma beam 25 is to be divided into several segments in the direction perpendicular to the direction in which the plasma beam 25 is traveling forward, it may be divided into any number of segments in the direction perpendicular to the traveling direction of the plasma beam 25, although the present invention should not be restricted to the three segments as shown in the examples of FIG. 3 (a), (c), and FIG. 4 (b), (c). In other words, the sheet magnet 27 can be divided into several segments in the direction perpendicular to the traveling direction of the plasma beam 25, if the sheet magnet 27 is provided so that it can provide the repulsion magnet field having the strength that is higher at the portion corresponding to the central side of the plasma beam 25 than that at the portion corresponding to the outer edge side of the plasma beam 25.

In the example shown in FIG. 4 (d), (e), the sheet magnet 27 that provides the repulsion magnet field having the strength that is higher at the portion corresponding to the central side of the plasma beam 25 than that at the portion corresponding to the outer edge side of the plasma beam 25 is divided into five segments 27a-27e. Like the example shown in FIG. 4 (b), (c), it is seen from the example of FIG. 4 (d), (e) that with regard to the gap between the permanent magnets 27a, 27a facing opposite each other at the portion corresponding to the central side, the respective gaps between the permanent magnets 27b, 27b and between the permanent magnets 27c, 27c, both of which face opposite each other at the portion corresponding to the outer edge side are greater, and the respective gaps between the permanent magnets 27d, 27d and between the permanent magnets 27e, 27e, both of which face opposite each other at the portion corresponding to the more outer edge side are much greater.

When the sheet magnet 27 that provides the repulsion magnetic field having the strength that is higher at the portion corresponding to the central side of the plasma beam 25 than that at the portion corresponding to the outer edge side of the plasma beam 25 is divided into several segments in the direction perpendicular to the traveling plasma beam 25 as described previously, it may take the following form. That is, the sheet magnet 27 that is divided into several segments may be such that the residual magnetic flux density of the permanent magnets at the portion corresponding to the central side of the plasma beam 25 can be greater than the residual magnetic flux density of the permanent magnets at the portion corresponding to the outer edge side of the plasma beam 25, and that the repulsion magnetic field strength provided by the permanent magnets facing opposite each other at the portion corresponding to the central side of the plasma beam 25 can be higher than the repulsion magnetic field strength provided by the permanent magnets facing opposite each other at the portion corresponding to the outer edge side of the plasma beam 25.

The form of the sheet magnet 27 described above is shown in FIGS. 5 (b) and (c).

As shown in FIGS. 5 (b) and (c), the sheet magnet 27 in the sheet magnet assembly employed in the sheet-like plasma generator of the present invention is divided into three segments, for example, each of which corresponds to a permanent magnet 27a, 27b and 27c. The central permanent magnet 27a, which provides the strong magnetic field, may be formed from any of the neodymium magnets (Nd—Fe—B) or any of samarium-cobalt magnets (Sm—Co), for example. Then, the repulsion magnetic field strength provided by the permanent magnets 27a, 27a facing opposite each other at the portion corresponding to the central side can be higher than the repulsion magnetic field strength provided by the permanent magnets 27b, 27b facing opposite each other at the portion corresponding to the outer edge side or the permanent magnets 27c, 27c facing opposite each other.

Although this is not shown, the area or volume of the central permanent magnet 27a on the side thereof facing opposite the plasma beam 25 may be larger than that of the outer permanent magnets 27b, 27c, or the repulsion magnetic field strength provided by the permanent magnets 27a, 27a facing opposite each other at the portion corresponding to the central side may be higher than the repulsion magnetic field strength provided by the permanent magnets 27b, 27b or 27c, 27c facing opposite each other at the portion corresponding to the outer edge side.

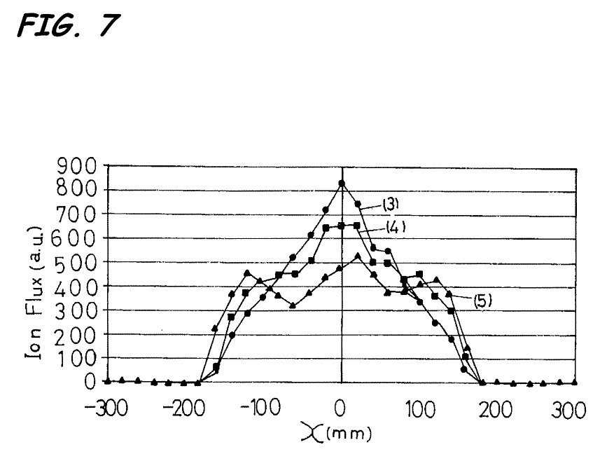

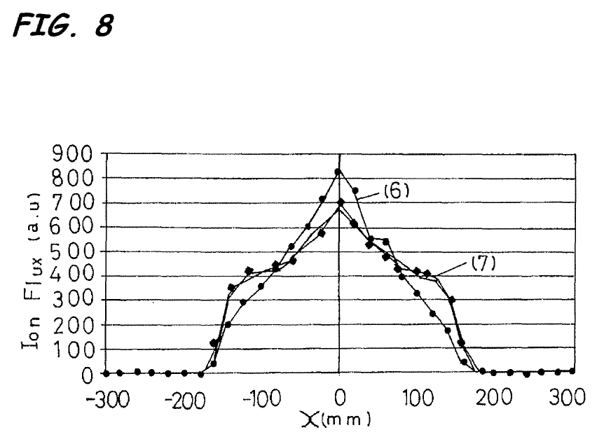

FIGS. 7 and 8 illustrate the ion flux distribution diagram for each of the different material types of the permanent magnets 27a, 27b, and 27c in the sheet magnet 27 divided into the three segments.

In FIG. 7, (3) represents the ion flux distribution of the prior art as for (1) in FIG. 6, and (4) and (5) represent the ion flux distribution for the central magnet 27a formed from any of the neodymium type magnets. In FIG. 7, the central magnet 27a in (5) is longer than that in (4). Accordingly, the outer permanent magnets 27b, 27c in (4) are shorter than that in (5).

In FIG. 8, (6) represents the ion flux distribution of the prior art as for (1) in FIG. 6, and (7) represents the ion flux distribution for the central magnet 27a formed from any of the samarium-cobalt type magnets.

When the central magnet 27a is formed from any of the magnet materials that provide the higher residual magnetic flux density, the ion flux distribution that presents the smooth mountain shape may be obtained, as compared against the ion flux distribution that presents the steep mountain shape with one high peak as shown in FIG. 6 (1) for the conventional sheet magnet 29 employed in the conventional sheet-like plasma generator shown in FIG. 4 (a) and FIG. 5 (a).

It may be appreciated from the above that the ion flux distribution of the plasma that evaporates the vapor deposition material 31 can be improved so that it can present the smooth mountain shape. Thus, the film deposition apparatus 10 in the sheet-like plasma generator of the present invention allows the film thickness distribution of the film being deposited on the surface of the substrate 33 to be flattened so that the film deposition can be performed over the wide area and with the uniform film thickness distribution.

In the preferred embodiment of the sheet-like plasma generator that is described here, the sheet magnet 27 of FIG. 4 (c) is used together with the conventional sheet magnet 29 of FIG. 4 (a), as shown in FIG. 3 (a). The following description presents one example of the film deposition process using the film deposition apparatus 10 of the present invention as shown in FIGS. 1 and 2.

In this example, argon gas is used as the plasma gas, which is introduced into the plasma gun 20 as indicated by an arrow 40. The film deposition process occurs on the substrate 33 under the following conditions that have been described for the conventional sheet-like plasma generator and film deposition apparatus 100 by referring to FIGS. 11 and 12 in the section “BACKGROUND”, except that oxygen is supplied into the film deposition chamber 30 as indicated by an arrow 41.

Material type: magnesium oxide (MgO)

Film thickness (target): 12000 Å

Deposition pressure: 0.1 Pa

Substrate temperature: 200° C.

Flow rate of Ar: 30 sccm (0.5 ml/sec)

Flow rate of O₂: 400 sccm (6.7 ml/sec)

File deposition rate: 175 Å/sec

The following describes the case in which the film deposition was performed on another substrate 33 under the same conditions as specified above, by using the sheet magnet assembly including two conventional pairs of sheet magnets 29 shown in FIG. 4 (a).

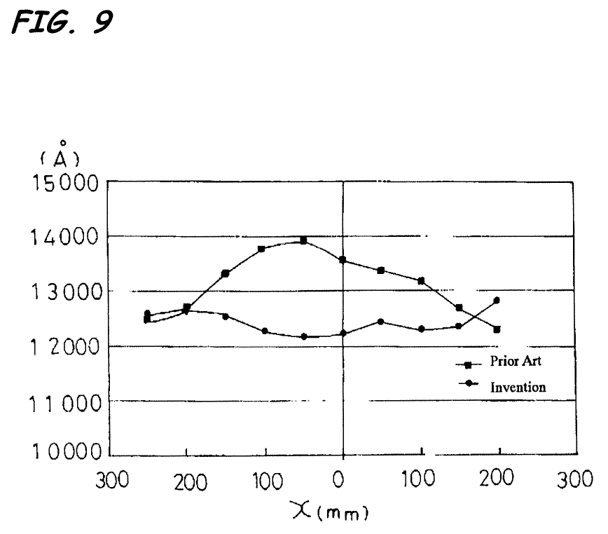

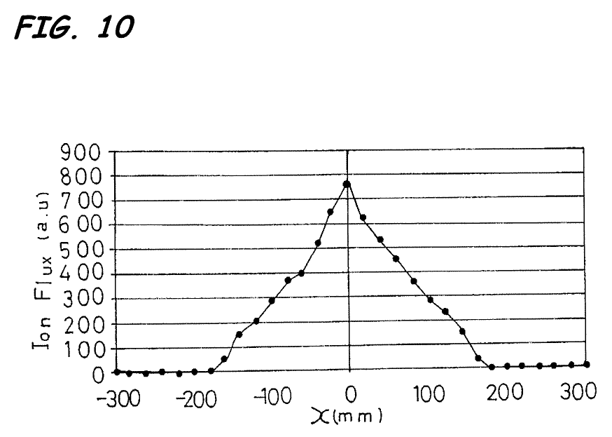

FIG. 9 shows two different film thickness distributions in graph forms, one of which represents the film thickness distribution as measured when the film deposition occurred by using the film deposition apparatus in conjunction with the sheet-like plasma generator of the present invention, and the other represents the film thickness distribution as measured when the film deposition occurred by using the sheet magnet assembly including two conventional pairs of sheet magnets 29 shown in FIG. 4 (a). In FIG. 9, the Y axis represents the film thickness (Å), and the X axis represents the distance (mm) of the direction (as indicated by an arrow x in FIG. 2) in which the plasma beam is being expanded into a sheet-like shape, with the center of the plasma beam 28 being designated as the origin (0).

It may be seen from FIG. 9 that the film thickness distribution curve becomes flat when the film deposition occurs by using the film deposition apparatus in conjunction with the sheet-like plasma generator of the present invention.

Although the present invention has been described with reference to the preferred embodiments of the present invention and examples thereof, it should be understood that the present invention is not restricted to those embodiments and examples, which may be modified in various ways without departing from the spirit and scope of the invention as defined in the appended claims.

1. A sheet-like plasma generator comprising:
a plasma gun for producing a plasma beam,
a convergence coil, and
a sheet magnet assembly including a pair of sheet magnets comprising permanent magnets extending in a direction perpendicular to a direction in which the plasma beam is traveling forward through the convergence coil, and the pair of sheet magnets are arranged in parallel with each other and facing opposite each other, so that the plasma beam passes through the magnetic fields developed by the pair of sheet magnets thereby deforming the plasma beam into a sheet-like plasma beam, wherein
at least one of the sheet magnets provides a repulsion magnet field having a strength that is higher at a portion corresponding to a central part of plasma beam than at a portion corresponding to an outer edge side of the plasma beam.

2. The sheet-like plasma generator as defined in claim 1, wherein the at least one sheet magnet that provides the repulsion magnet field having the strength that is higher at the portion corresponding to the central part of plasma beam than at the portion corresponding to the outer edge side of the plasma beam is divided into several segments in the direction perpendicular to the direction in which the plasma beam travels.

3. The sheet-like plasma generator as defined in claim 2, wherein in the at least one sheet magnet that is divided into several segments, the permanent magnets at the portion corresponding to the central part of the plasma beam are located closer to the plasma beam than the permanent magnets at the portion corresponding to the outer edge side of the plasma beam, and wherein a distance between the permanent magnets facing opposite each other at the portion corresponding to the central part is smaller than a distance between the permanent magnets facing opposite each other at the portion corresponding to the outer edge side.

4. The sheet-like plasma generator as defined in claim 2, wherein in the sheet magnet that is divided into several segments, a residual magnetic flux density of the permanent magnets at the portion corresponding to the central part of the plasma beam is greater than that of the permanent magnet at the portion corresponding to the outer edge side of the plasma beam, and wherein the repulsion magnetic field developed by the permanent magnets facing opposite each other at the portion corresponding to the central part is higher than that of the permanent magnets facing opposite each other at the portion corresponding to the outer edge side.

5. A film deposition apparatus for use in conjunction with the sheet-like plasma generator according to claim 1, wherein the film deposition apparatus includes:
a film deposition chamber from which the air may be evacuated to place the film deposition chamber in a vacuum state,
a vapor deposition material dish arranged within the film deposition chamber for holding a suitable vapor deposition material, and
a substrate holder for supporting a substrate on which a film is being deposited is in a position facing opposite the vapor deposition material dish and spaced away from the same,
whereby the film deposition occurs on the substrate by exposing the vapor deposition material to the sheet-like plasma beam generated by the sheet-like plasma generator, thereby causing the vapor deposition material to evaporate.

6. The film deposition apparatus as defined in claim 5, wherein the substrate on which a film is being deposited moves in parallel with the vapor deposition material dish within the film deposition chamber.

7. A film deposition method for use in conjunction with the sheet-like plasma generator according to claim 1, wherein the method comprises:
holding a substrate on which a film is being deposited in a position facing opposite a vapor deposition material dish placed within a film deposition chamber from which air can be evacuated to place it in a vacuum state and spaced away from vapor deposition material in the vapor disposition material dish; and
depositing a film on the substrate by exposing the vapor deposition material to the sheet-like plasma beam generated by the sheet-like plasma generator, thereby causing the vapor deposition material to evaporate.

8. The film deposition method as defined in claim 7, further including a step of moving substrates on which films are being deposited in parallel with the vapor deposition material dish within the film deposition chamber and thereby depositing films on the substrates successively while they are moving.

9. A film deposition apparatus for use in conjunction with the sheet-like plasma generator according to claim 2, wherein the film deposition apparatus includes:
a film deposition chamber from which the air may be evacuated to place the film deposition chamber in a vacuum state,
a vapor deposition material dish arranged within the film deposition chamber for holding a suitable vapor deposition material, and
a substrate holder for supporting a substrate on which a film is being deposited in a position facing opposite the vapor deposition material dish and spaced away from the same,
whereby the film deposition occurs on the substrate by exposing the vapor deposition material to the sheet-like plasma beam generated by the sheet-like plasma generator, thereby causing the vapor deposition material to evaporate.

10. A film deposition apparatus for use in conjunction with the sheet-like plasma generator according to claim 3, wherein the film deposition apparatus includes:
a film deposition chamber from which the air may be evacuated to place the film deposition chamber in a vacuum state,
a vapor deposition material dish arranged within the film deposition chamber for holding a suitable vapor deposition material, and
a substrate holder for supporting a substrate on which a film is being deposited in a position facing opposite the vapor deposition material dish and spaced away from the same,
whereby the film deposition occurs on the substrate by exposing the vapor deposition material to the sheet-like plasma beam generated by the sheet-like plasma generator, thereby causing the vapor deposition material to evaporate.

11. A film deposition apparatus for use in conjunction with the sheet-like plasma generator according to claim 4, wherein the film deposition apparatus includes:
a film deposition chamber from which the air may be evacuated to place the film deposition chamber in a vacuum state,
a vapor deposition material dish arranged within the film deposition chamber for holding a suitable vapor deposition material, and
a substrate holder for supporting a substrate on which a film is being deposited in a position facing opposite the vapor deposition material dish and spaced away from the same,
whereby the film deposition occurs on the substrate by exposing the vapor deposition material to the sheet-like plasma beam generated by the sheet-like plasma generator, thereby causing the vapor deposition material to evaporate.

12. A film deposition method for use in conjunction with the sheet-like plasma generator according to claim 2, wherein the method includes steps of
holding a substrate on which a film is being deposited in the position facing opposite the vapor deposition material dish placed within a film deposition chamber from which the air can be evacuated to place it in the vacuum state and spaced away from the vapor deposition material on its dish; and
depositing a film on the substrate by exposing the vapor deposition material to the sheet-like plasma beam generated by the sheet-like plasma generator, thereby causing the vapor deposition material to evaporate.

13. A film deposition method for use in conjunction with the sheet-like plasma generator according to claim 3, wherein the method includes steps of
holding a substrate on which a film is being deposited in the position facing opposite the vapor deposition material dish placed within a film deposition chamber from which the air can be evacuated to place it in the vacuum state and spaced away from the vapor deposition material on its dish; and
depositing a film on the substrate by exposing the vapor deposition material to the sheet-like plasma beam generated by the sheet-like plasma generator, thereby causing the vapor deposition material to evaporate.

14. A film deposition method for use in conjunction with the sheet-like plasma generator according to claim 4, wherein the method includes steps of
holding a substrate on which a film is being deposited in the position facing opposite the vapor deposition material dish placed within a film deposition chamber from which the air can be evacuated to place it in the vacuum state and spaced away from the vapor deposition material on its dish; and
depositing a film on the substrate by exposing the vapor deposition material to the sheet-like plasma beam generated by the sheet-like plasma generator, thereby causing the vapor deposition material to evaporate.
